(19) United States
(12) Patent Application Publication
(10) Pub. No.: US 2019/0041447 A1
(43) Pub. Date: Feb. 7, 2019

(54) NON-CLAMPING METHOD AND APPARATUS FOR IDENTIFICATION OF DEAD UNDERGROUND POWER UTILITY CABLE FROM SPATIALLY ADJACENT POWER UTILITY CABLES

(71) Applicant: SP PowerAssets Limited, Singapore (SG)

(72) Inventors: Aimin Wang, Singapore (SG); Kim Hoong Alvis Lee, Singapore (SG); Hongqun Li, Singapore (SG)

(21) Appl. No.: 16/151,649

(22) Filed: Oct. 4, 2018

Related U.S. Application Data
(63) Continuation of application No. PCT/SG2017/050193, filed on Apr. 5, 2017.

(30) Foreign Application Priority Data
Apr. 8, 2016 (SG) 10201602767R

(51) Int. Cl. G01R 31/08; G01R 31/28; G01R 31/02; G01R 31/12

(52) U.S. Cl. CPC G01R 31/083; G01R 31/2841; G01R 31/1209; G01R 31/086; G01R 31/021

(57) ABSTRACT

The present disclosure relates to non-clamping method and apparatus for identification of dead underground power utility cable. The method comprises: forming a complete circuit by connecting a transmitter to two of a plurality of conductors of a target dead power cable at a first end thereof; short-circuiting and grounding the plurality of conductors at a second end of the dead power cable; injecting an audio frequency current signal from the transmitter into the complete circuit; within a pit which at least partially exposes a plurality of underground power cables: detecting a first audio frequency magnetic flux signal on a surface of a random first one of the underground power cables; detecting a second plurality of audio frequency magnetic flux signal on respective surfaces of some of the underground power cables being spatially-adjacent to the first one of the underground power cables; identifying the first one of the underground power cables as the target dead power cable if a peak amplitude of the first audio frequency magnetic flux signal as displayed on a display device exceeds any peak amplitude of the second plurality of audio frequency magnetic flux signals as displayed on the display device by more than about 50%.

### CROSS REFERENCE TO RELATED APPLICATIONS

This application is a continuation application of International Application No. PCT/SG2017/050193 filed on Apr. 5, 2017, which claims priority to and the benefit of the filing of Singapore Patent Application No. 10201602767R filed on Apr. 8, 2016, and the specification and claims thereof are incorporated herein by reference.

### TECHNICAL FIELD

Embodiments of the invention relate to non-clamping method and apparatus for positive identification of a dead insulated and/or armoured electrical underground cable with twisting multi-conductor in excavation joint pit or cable basements in utility power substations.

### BACKGROUND

Cable identification is defined as the positive selection of a particular cable that lies within a bunch of cables, and is necessary when cables need to be diverted for reasons such as, but not limited to, re-routing of roads, construction of culverts, looping in and out to a new substation from an existing distribution network and facilitating cable fault repairs.

Cable identification at cable termination in electric utility substation is straight-forward, however, cable identification at intermediate cable portions is more complicated especially if the intermediate cable portions are buried underground together with many similar power utility cables in close proximity in urban areas due to congestion and if underground conditions are complex. Accordingly, underground cable identification in urban areas is fraught with difficulties and prone to wrong identification.

Many existing cable identification methods, known as current transducer (CT) type, identify the dead cable mainly by determining current pulse polarity. Examples are described by U.S. Pat. No. 3,924,179, US Patent Application Publication No. 2004/0145486 A1. CT type methods face many issues: CT clamping must be in the correct direction—incorrect clamping direction will result in identification of wrong cable; the risk of incorrect clamping direction is increased if a cable in a joint pit has a ‘S’ shape or ‘U’ turn route; CT clamping contacts can become unreliable due to dust and dirt in the joint pit. Any clamping method including non-CT type such as EP Patent Application Publication EP1014099 A2 requires every cable to be tested (clamped) be fully excavated which is not always possible especially in highly congested urban areas.

Certain other methods, known as audio type (AT), apply audio frequency signal (tone) to cable conductors and use a probe to pick up the tone in field to do cable tracing or identification without clamping around the cable under test. Some examples are described by U.S. Pat. Nos. 7,116,093, 5,887,051, 6,946,850, US Patent Application Publication No. 2010/0176794, CA 2537927A1/WO 2004/079377A2, U.S. Pat. No. 6,163,144, U.S. Pat. No. 6,127,827, GB 889452 A. These publications are mostly related to communication wire tracing, low voltage live power wire tracing or specific Digital Signal Processing (DSP) technique like compressed filtration. They are not relevant to power utility cables with armouring, twisting conductors and wide voltage range from LV (such as 400VAC) to HV (such as 66kVAC) and they do not provide a reliable method to identify dead power utility cables from its adjacent power utility cables of close proximity, live or dead.

### SUMMARY

According to one embodiment, a non-clamping method for identification of target dead underground power cable is provided. The method comprises:
forming a complete circuit by connecting a transmitter two of a plurality of conductors of a target dead power cable at a first end thereof;
short-circuiting and grounding the plurality of conductors at a second end of the target dead power cable;
injecting an audio frequency current signal from the transmitter into the complete circuit for generating an audio frequency magnetic flux signal on a surface of the target dead power cable;
   within a pit which at least partially exposes a plurality of underground power cables:
detecting a first audio frequency magnetic flux signal on a surface of a random first one of the underground power cables;
detecting a second plurality of audio frequency magnetic flux signal on respective surfaces of some of the underground power cables being spatially-adjacent to the first one of the underground power cables; and
identifying the first one of the underground power cables as the target dead power cable if a peak amplitude of the first audio frequency magnetic flux signal as displayed on a display device exceeds any peak amplitude of the second plurality of audio frequency magnetic flux signals as displayed on the display device by more than about 50%.

According to one embodiment of the invention, a receiver for identification of target dead underground power cable is provided. The receiver comprises:
an amplifier circuitry configured to amplify a picked-up signal by a user-adjustable gain;
a by-passable switched capacitor analogue ultra-narrow bandpass filter configured to filter an output of the amplifier circuitry;
a gain calibrator circuitry configured to calibrate an output of the by-passable switched capacitor analogue ultra-narrow bandpass filter to form a normalised signal level;
a speaker circuitry configured to broadcast an output of the gain calibrator circuitry;
a micro-controller unit (MCU) having an Analogue Digital Converter (ADC) configured to digitise the output of the gain calibrator circuitry; and
a display circuitry configured to receive an output of the MCU to provide a visual indication thereof on a display device, wherein a displayed magnitude of the visual indication is correlated to an amplitude of an audio frequency magnetic flux signal comprised in the picked-up signal.

According to one embodiment of the invention, a transmitter for identification of target dead underground power cable is provided. The transmitter comprises:
a micro-controller unit (MCU) having an audio signal generator configured to generate an audio frequency voltage signal;
a current selector circuitry configured to preset a peak pulse amplitude;
a constant peak current source circuitry configured to convert the audio frequency voltage signal into an audio frequency current signal having the preset peak pulse amplitude; and
an output protection circuitry electrically coupled between the constant peak current source circuitry and a pair of output terminals, and configured to prevent over-current and over-voltage damage to the transmitter, wherein the pair of output terminals are configured to inject the audio frequency current signal into a pair of conductors of a target dead power cable.

According to one embodiment of the invention, a system for cable identification is provided. The system comprises:
a transmitter as described above and/or in the present disclosure; and
a receiver as described above and/or in the present disclosure, wherein the audio frequency magnetic flux signal comprised in the picked-up signal is detected from the target dead power cable.

### BRIEF DESCRIPTION OF DRAWINGS

Embodiments of the invention are disclosed hereinafter with reference to the drawings, in which:

FIG. 1A is a schematic diagram illustrating a set-up for underground target dead power cable identification according to one embodiment of the invention;

FIG. 1B illustrates a non-clamping method for underground target dead power cable identification, which is described with reference to FIG. 1A;

FIG. 2 shows one method f locating signal when comparing a pair of adjacent cables;

FIG. 3 illustrates a cyclic peak to a trough pattern in detected signal amplitude or strength at different positions along a cable length due to twisting of multi-conductors within a target dead power cable;

FIG. 4 shows a pick-up coil geometrically centred on a magnetic shield;

FIGS. 5A and 5B show cross-sectional views of running a pick-up coil along surfaces of adjacent cables in zones Z1 and Z2 When comparing each pair of cables;

FIGS. 6A and 6B show cross-sectional views of running a pick-up coil in conjunction with a magnetic shield when comparing each pair;

FIG. 7A is a schematic representation of a transmit

FIG. 7B is a signal flow and control block diagram of the transmitter of FIG. 7A;

FIG. 8A is a schematic representation of a receiver;

FIG. 8B is a signal flow and control block diagram of the receiver of FIG. 8A; and

FIG. 9 shows one example of the plurality of piecewise linear sensitivity relationships implemented in the receiver.

### DETAILED DESCRIPTION

In the following description, numerous specific details are set forth in order to provide a thorough understanding of various illustrative embodiments of the invention. It will be understood, however, to one skilled in the art, that embodiments of the invention may be practiced without some or all of these specific details. In other instances, well known process operations have not been described in detail in order not to unnecessarily obscure pertinent aspects of embodiments being described. In the drawings, like reference numerals refer to same or similar functionalities or features throughout the several views,

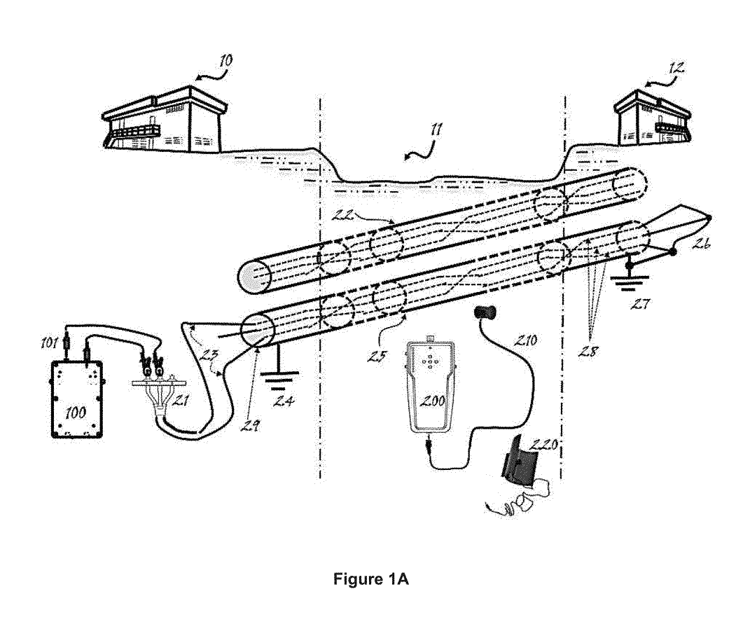

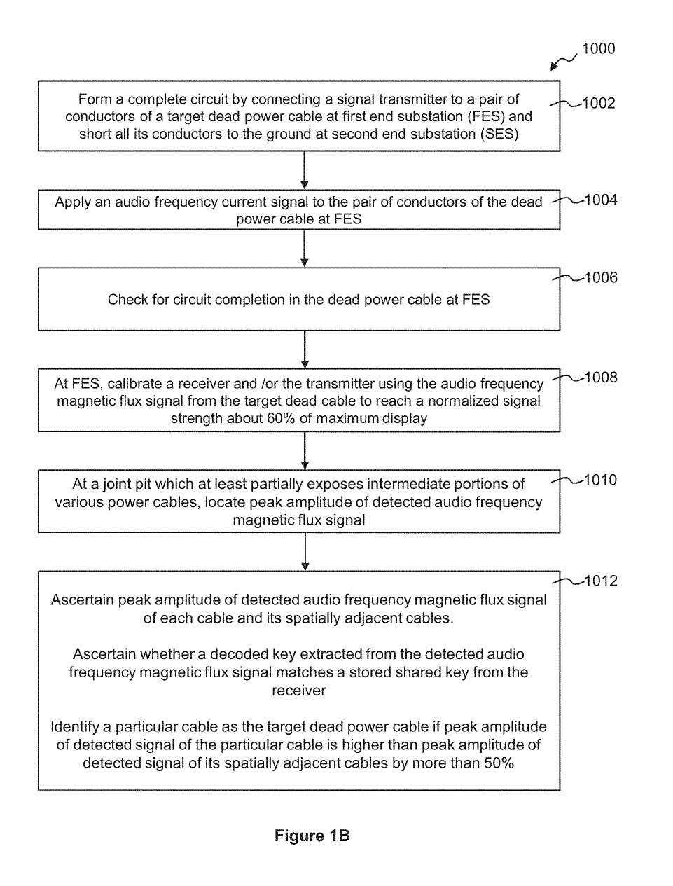

FIG. 1A is a schematic diagram illustrating a set-up for underground cable identification according to one embodiment of the invention. As illustrated in FIG. 1A, a target dead power cable 25 and one of its neighbouring power cables 22 are buried underground. For the target dead power cable 25, its cable terminations are accessible at a First End Substation (FES) 10 and a Second End Substation (SES) 12. The power cable 22 may or may not be terminated at FES 10 and or SES 12. The intermediate portions of the various power cables 22, 25 are buried underground. For the purposes of cable work and/or identification, a joint pit 11 is excavated which at least partially exposes some of the power cables 22, 25 at their intermediate portions. The target power cable 25 is twisting multi-conductor type, e.g. 300 mm² XLPE 22 kV Copper 3 Core cable, while the neighbouring power cable 22 may be the same or different types and buried for electric power distribution or transmission.

FIG. 1B illustrates a non-clamping method 1000 for identification of dead underground cable identification, which is described with reference to FIG. 1A.

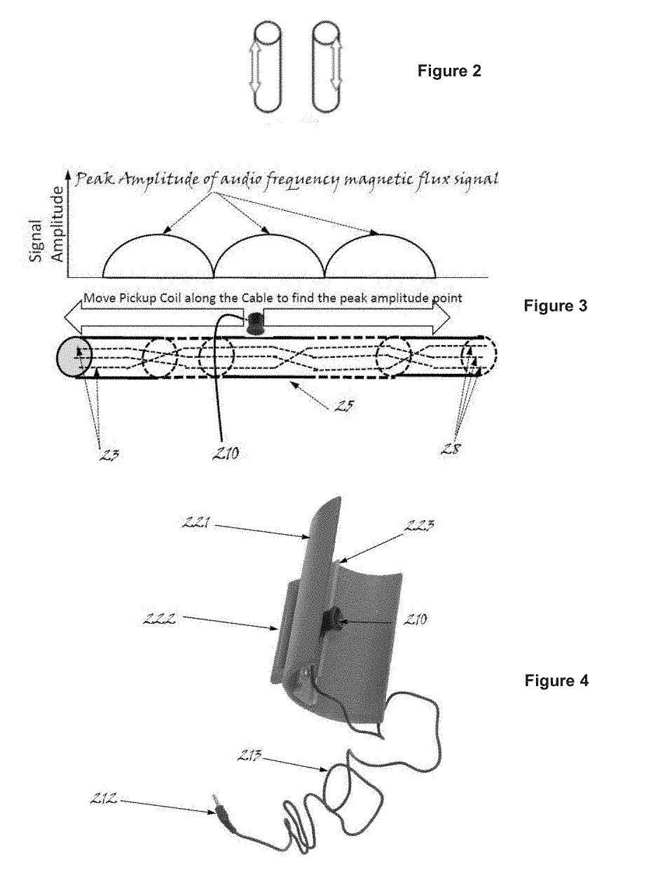

In block 1002, a complete circuit is formed with a pair (two) 23 of a plurality of conductors 28 (FIGS. 1A and 3) of the target dead power cable 25. At a first end of a target dead power cable 25, i.e. at the FES 10, a transmitter 100 is connected to this conductor pair 23. At a second end substation of the target dead power cable 25 i.e. at the SES 12, all of the conductors are shorted and grounded by using a jumper wire 26 or switchgear earth switch. Optionally, the armour 29 (FIGS. 1A, 5A and 6B) of the target dead power cable 25 is grounded at 24 in the first end substation and at 27 in the second end substation that hosts the cable terminations of the target dead power cable 25. This step of grounding the armour 29 enhances safety of human users involved in carrying out various steps in the identification of target dead underground power cable.

In block 1004, using a transmitter 100, an audio frequency current signal is injected into the completed circuit. The audio frequency current signal is to generate an audio frequency magnetic flux signal on a surface of the target dead power cable 25. To this purpose, a pair of tone output wires 101 is provided at the transmitter 100 and is connected to the pair of conductors 23 via a cable termination 21. The applied audio frequency current signal travels through the complete circuit formed in block 1002. The earth path is excluded from the complete circuit in which the applied audio frequency current signal flows.

In block 1006, the circuit formed in block 1002 is verified for circuit completion. This verification may be performed by the transmitter 100 which is configured to perform a circuit completion check. The transmitter 100 is further configured to provide suitable notifications such as by LED indicator, to present the verification result, i.e. whether the circuit is verified complete or incomplete.

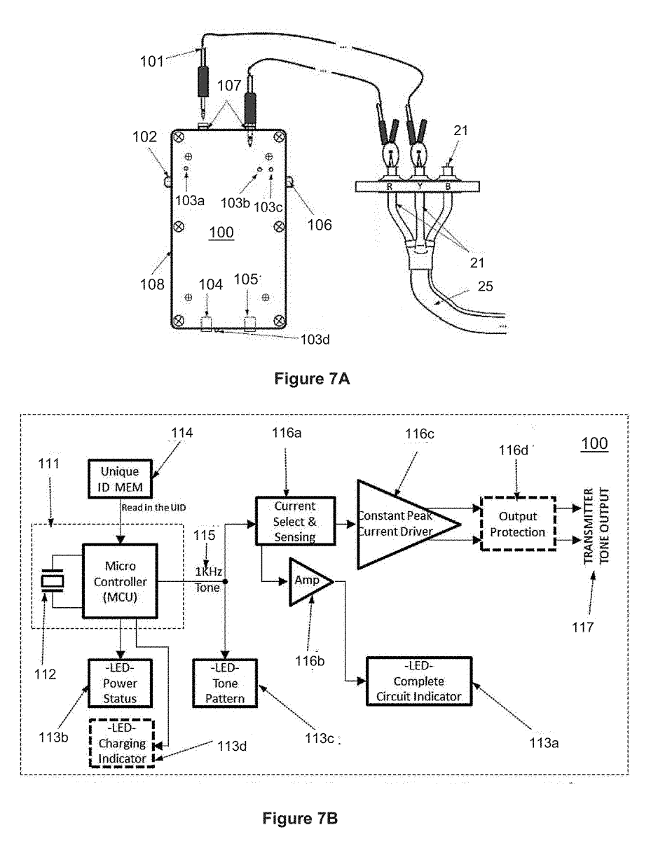

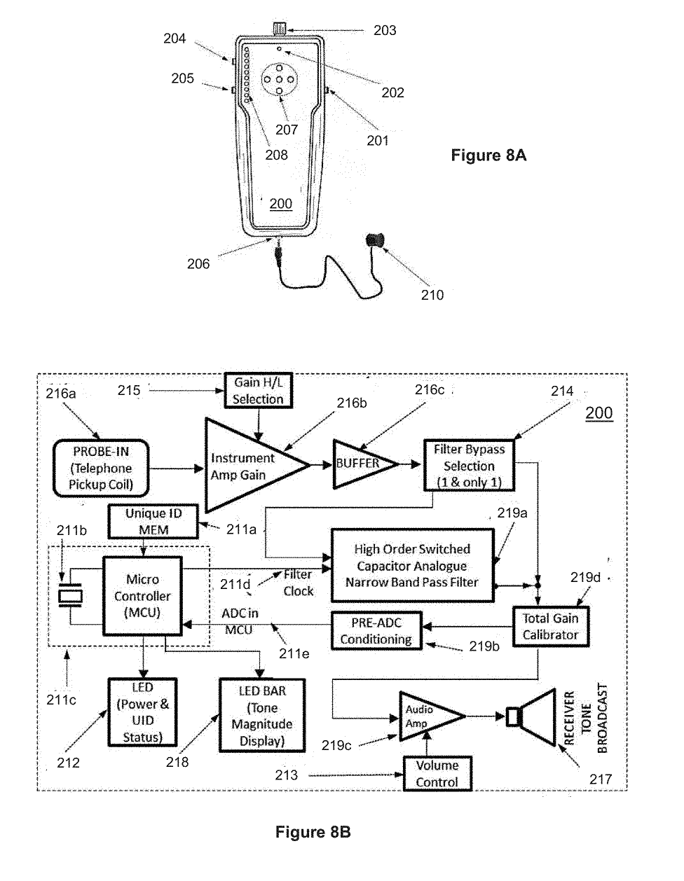

In block 1008, in the FES 10 with the target dead cable known at cable termination, the receiver 200 and/or transmitter 100 may be calibrated to maximize spatial resolution of distinctness. For example, if the peak amplitude of a detected audio frequency magnetic flux signal produces a display output of less than 50% of the displayable length, e.g. less than 5 LED bar indicators, the receiver 200 and/or the transmitter 100 is adjusted to increase output amplitude so that the detected peak amplitude of the audio frequency magnetic flux signal produces a normalized level display output of about 60%, e.g. 6 LED bar indicators. The calibration can be done via adjusting switch 106 in FIG. 7A and switch 205 in FIG. 8A though in most cases the calibration is not necessary when the detected peak amplitude of audio frequency magnetic flux signal produces a display output of 60% which is a factory calibrated level for the most popular cable types in the electric utility network.

In block 1010, at an excavated joint pit 11 which at least partially exposes intermediate portions of various power cables 22, 25, the wall and floor of the joint pit 11 and along every exposed cable surface in the joint pit 11 are screened to locate a peak amplitude of audio frequency magnetic flux signal which is generated by the applied audio frequency current signal in block 1004. This is done by using an audio pick-up coil 210 which is electrically coupled to a receiver 200. The receiver 200 includes a speaker that is configured to broadcast a detected audio frequency magnetic flux signal, and a display device 208 (FIG. 8A) that is configured to display the amplitude of a detected audio frequency magnetic flux signal.

In block 1012, identification of the target dead power cable 25 takes place by comparing peak amplitude of audio frequency magnetic flux signal detected at each cable against that of its spatially-adjacent cables. Starting from the location or cable where the peak amplitude of audio frequency magnetic flux signal was detected (in block 1010) or starting from a random cable, for each of the neighbouring cables spatially-adjacent to this location or cable, peak amplitude of audio frequency magnetic flux signal detected at the surface of each neighbouring cable are ascertained and compared. During this comparison, signal gain level control of the receiver 200 and transmitter 100 should not be adjusted.

In practice, a pick-up coil 210 is longitudinally run along the lengthwise direction, for example 1.5 m to 2 m along the surface of each spatially-adjacent neighbouring cable. If an audio frequency magnetic flux signal is detected, the display device 208 of the receiver 200 will display the signal amplitude which cycles through a peak to a trough value as the pick-up coil 210 is moved along the cable length. FIG. 3 illustrates a cyclic pattern in detected signal magnitude or strength at different positions along a cable length due to twisting nature of multi-conductors within a dead power cable. However, it is the peak amplitude of audio frequency magnetic flux signal, i.e. maximum bar length displayed or lighted on the display device, which is recorded as the peak amplitude of audio frequency magnetic flux signal detected for each cable.

A power cable is successfully identified as the target dead power cable when the peak amplitude of audio frequency magnetic flux signal of the target power cable exceeds any detected peak amplitude of audio frequency magnetic flux signal of its spatially-adjacent cables by more than about fifty per cent (50%). As an illustrative example, peak amplitude of audio frequency magnetic flux signal detected from the target dead power cable may produce a display output of 6 bar indicators while peak amplitude of audio frequency magnetic flux signal detected from neighbouring cables spatially-adjacent to the target dead power cable may produce a display output of 3 or less bar indicators.

To prevent detecting and using irrelevant magnetic flux signals resulting from unrelated dead power cable identification task(s) that are being performed in the vicinity at the same time and using the same transmitter and receiver device model, block 1012 includes extracting a decoded key from a detected audio frequency magnetic flux signal and ascertaining whether the decoded key matches a shared key stored in the receiver 200. As the shared key is exclusively stored in the transmitter 100 and receiver 200 paired therewith, this procedure ensures that the detected signal is resulted from the transmitter being used in block 1004 and provides differentiation from unrelated signals resulting from other transmitters being concurrently used. If the decoded key does not match the stored key, a notification is presented. Such notification may take on one or more forms including, but not limited to, display an error indication on the display device, inactivate the display device 208 to prevent display of the detected audio frequency magnetic flux signal. If the decoded key matches the stored key, the display device 208 of the receiver 200 is allowed to display the amplitude of the detected audio frequency magnetic flux signal.

FIG. 2 shows one method of detecting peak amplitude of audio frequency magnetic flux signal when comparing a pair of adjacent cables. This pair of adjacent cables can be arranged in left-right or above-below in a three-dimensional relation. When locating the peak audio frequency magnetic flux signal point for each cable in the pair, the pick-up coil 210 is longitudinally run along lengthwise portions of the respective cable surface as far apart as possible from the other cable in the comparison. The cord (213 in FIG. 4) of pick-up coil 210 should also be maintained substantially perpendicular to the cable length direction as it is being run.

It is to be appreciated that the pick-up coil 210 may be used individually or in conjunction with a magnetic shield 221 to reduce interference due to neighbouring magnetic fields. FIG. 4 shows a pick-up coil 210 geometrically centred on a magnetic shield 221. Particularly, at an inner side of the magnetic shield 221, a coil holder 223 is provided to retain a pick-up coil 210 at the centre of the shield 221. The shield 221 may be provided as a C-shape or arc shape. The shield 221 includes material with good magnetic permeability such as cast iron. The shield 221 may be provided with a handle 222.

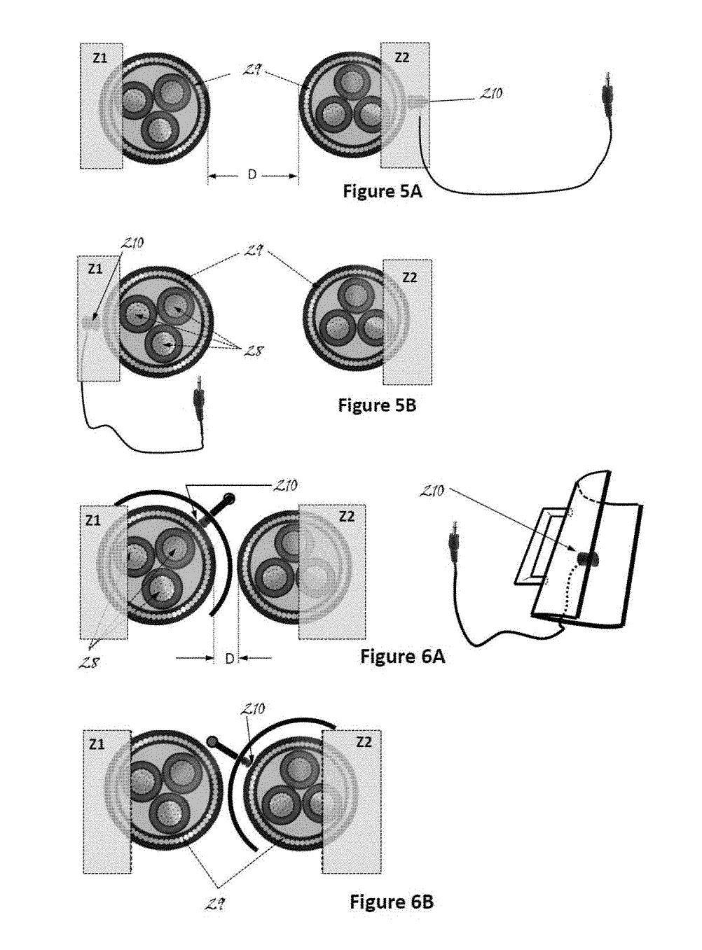

FIGS. 5A and 5B show cross-sectional views of running the pick-up coil 210 along surfaces of adjacent cables in zones Z1 and Z2. In certain circumstances where distance (D) between adjacent cables is greater than 10 cm, the pick-up coil 210 can be used without a magnetic shield 221. In other circumstances where a distance (D) is between 2 cm to 10 cm, the pick-up coil 210 may still be used without a magnetic shield 221 when zones Z1 and Z2 are accessible

FIGS. 6A and 6B show a similar arrangement as FIGS. 5A and 5B. However, in FIGS. 6A and 6B, a distance (D) between adjacent cables is between 2 cm to 10 cm and, further, zones Z1 and Z2 are not accessible, e.g. the cable is blocked or partially buried. In this situation, the pick-up coil 210 may be used in conjunction with a magnetic shield 221. The magnetic shield 221 is configured to re-distribute the tone magnetic flux from the true signal source cable of this cable pair to its opening and return with decreased amount of flux passing through the pick-up coil 210 mounted in the inner centre of the magnetic shield 221. This will boost the tone signal amplitude difference to indicate the true signal source he measuring points are constrained spatially, i.e. too close to each other.

FIG. 7A is a schematic representation of the transmitter 100. The transmitter 100 is provided with a power ON/OFF switch 102, complete circuit indicator (amber LED) 103a, power on indicator (green LED) 103b, tone pattern indicator (LED configured to blink according to tone pattern) 103c, battery charging indicator LED 103d, 12V DC-in jack for battery charging 104 (for this embodiment, during charging, the power ON/OFF switch 102 should be in OFF position), 12V DC-in jack for normal transmitter 100 operation 105 (when power ON/OFF switch 102 is switched to ON), output level switch (HIGH—peak 3 Amperes; LOW—peak 1 Ampere) 106, output jacks 107, metal casing 108 holding PCBA and NiMH rechargeable battery pack.

To connect the transmitter 100 to the target dead power cable, alligator-clip-banana-plugs 101 are used to electrically couple the transmitter 100 output to the termination 21 of the pair of conductors of the target dead power cable. The termination 21 is in turn electrically coupled to the pair of single phase conductors 23 of the dead power cable 25.

FIG. 7B is a signal and control block diagram of the transmitter 100.

A micro controller unit (MCU) 111 is provided with a crystal 112 configured to generate an audio frequency voltage signal e.g. 1023 Hz tone 115. The MCU 111 is also configured to monitor battery voltage and control a display circuitry which includes indicator LEDs (power status LED 113b, tone pattern LED 113c, battery charging indication LED 113d). The MCU 111 may be provided with a 30 ppm 3.2768 MHz crystal 112 as the root source of clock.

A current selector circuitry 116a is electrically coupled to the MCU 111 and used to configure the preset peak pulse amplitude for the audio frequency current signal 117 to be output from the transmitter 100. The current selector circuity 116a, amplifier 116b and indicator 113a provide a current sensing circuitry configured to verify whether a circuit connected to the transmitter 100 is complete and presents the verification result via indicator 113a.

A constant peak current source circuitry (constant peak current driver) 116c is electrically coupled to the current selector 116a and configured to convert an audio frequency voltage signal into an audio frequency current signal having the preset peak current pulse amplitude.

An output protection circuitry 116d is electrically coupled to the constant peak current source circuitry 116c and configured to prevent damage to the transmitter 100 due to any over-voltage, over-current and transient cable inductance kickbacks.

A pair of output terminals 117 are electrically coupled to the output protection circuitry 116d and configured to inject the transmitter output, i.e., audio frequency current signal, into a pair of conductors 23 of a target dead power cable.

A memory circuitry 114 is electrically coupled to the MCU 111 and configured to store a shared key which is exclusive to the transmitter 100 and a receiver 200 paired therewith. The MCU 111 is configured to read the shared key from the memory 114 and encode the shared key into the audio frequency voltage signal derived from the stable clock source, i.e. the crystal 112,

FIG. 8A is a schematic representation of the receiver 200 which is configured to be removably coupled to the pick-up coil 210. The receiver 200 is provided with a power ON/OFF switch 201, power state indication LED 202, speaker volume control knob 203, filter ON/BYPASS switch 204, Analogue Front End amplitude switch (HIGH/LOW) 205, pick-up coil 210 plug-in jack 206, speaker 207, display device 208 comprising LED bar indicators (e.g. 10-LED bars) or other indicators for communicating signal magnitude. It is to be appreciated that the display device 208 may be provided as a LCD or LED panel.

FIG. 8B is a signal and control block diagram of the receiver 200.

An input terminal 216a is configured to receive picked-up signals from the pick-up coil 210, which picks up both audio frequency magnetic flux signal and electromagnetic noises such as mains hum and its harmonics.

An amplifier circuitry 216b is electrically coupled to the input terminal 216a and configured to amplify a picked-up signal by a user-adjustable gain via an external gain selector switch 215.

A by-passable switched capacitor analogue ultra-narrow bandpass filter 214, 219a is electrically coupled to the amplifier circuitry 216b for filtering the amplified picked-up signal and, more particularly, extracting an audio frequency magnetic flux signal of a predetermined frequency from the amplified picked-up signal.

An internal gain calibrator circuitry 219d is electrically coupled to the by-passable switched capacitor analogue ultra-narrow bandpass filter 214, 219a and configured with filtered signal path to generate a factory-calibrated magnitude for the audio frequency magnetic flux signal from the filtered picked-up signal, i.e. an output of the filter 219a. The internal gain calibrator circuitry 219d is calibrated in factory for filtered signal from ultra-narrow bandpass filter 219a to match a normalized 6-LED-bar on the surface of 2-metre utility power cable sample that is most popularly used.

A speaker circuitry 219c, 217 is electrically coupled to the gain calibrator circuitry 219d and configured to receive and broadcast the calibrated and filtered picked-up signal or the unfiltered picked-up signal, i.e. an output of block 219d.

The output signal from block 219d is processed by a pre-ADC: (Analogue Digital Conversion) conditioning circuitry 219b which then transmits an ADC input 211e to a micro-controller unit (MCU) system 211c.

The MCU 211c is configured to generate the switched capacitor filter clock 211d, monitor battery voltage and control the indicator LEDs. A 30 ppm 3.2768 MHz crystal 211b as the root source of clock is electrically coupled to the MCU 211c. The MCU 211c includes an Analogue to Digital Converter (ADC) which is further configured to digitise the calibrated and filtered picked-up signal, i.e. an output of block 219d or unfiltered picked-up signal which has been conditioned by block 219b prior to input to the ADC.

For the filtered picked-up signal, the ADC of the MCU 211c is further configured to digitise the output of the internal gain calibrator circuitry 219d based on a plurality of piecewise linear sensitivity relationships between the output of the pre-ADC circuitry 219b and peak amplitude to be displayed on the display device 208, i.e., LED bar indicators.

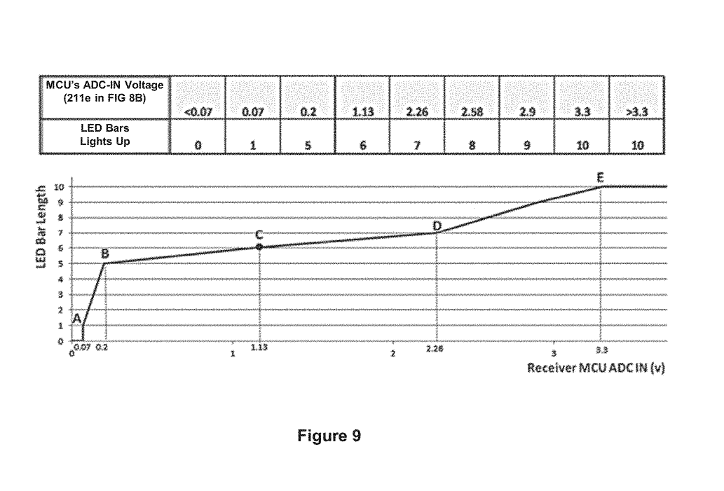

FIG. 9 shows one example of the plurality of piecewise linear sensitivity (also referred to as piecewise linear multiple virtual sensitivity, PLMVS) relationships implemented in the receiver 200. A normalised signal level is defined at 6-LED-bar at any underground power cable's peak audio frequency magnetic flux signal point, i.e. at point C which is calibrated in factory using the 300 mm² copper XLPE cable (2 meters cable sample with zero Ohm loop-back impedance). Gradient of slope BD is selected such that for majority of underground power cables, the peak amplitude of audio frequency magnetic flux signal with the pick-up coil 210 touching the peak amplitude point on the cable surface will display a length of 5 to 7 LED bars. With suitable choices of injected audio frequency current signal magnitude and frequency, the PLMVS relationships ensure the predetermined LED bar length displayed is as follows: within the range of B to E when the pick-up coil is touching the cable's peak amplitude point; within the range of A to B when the pick-up coil 210 is lifted up within 10 cm from that peak amplitude point of the cable surface; within dead band below point A (i.e. no LED bar lights up) when the pick-up coil 210 is lifted more than 10cm from the cable surface. The slope of AB is much steeper than BC and CD, and is slightly steeper than The slope of DE is steeper than BC and CD to allow quick saturation which may occur at cable termination where there is higher leakage flux due to removed armoring. The dynamic range of DE is mainly for split cable conductor or pilot wire that has no armoring. After point E, sensitivity is virtually saturated. The dead band below point A also provides noise floor filtering function.

A display circuitry 218 (including LED bar tone magnitude display device 208) is electrically coupled to the MCU 211c and configured to receive an output of the MCU 211c, i,e. the digitised output of the gain calibration circuitry 219d. A visual indication of this output is provided on the display device 208 in which the displayed magnitude of the visual indication is correlated to an amplitude of an audio frequency magnetic flux signal comprised in the picked-up signal which was received at 216a and has since been filtered by 219a.

A volume controller 213 is electrically coupled to the speaker circuitry 219c, 217 for adjusting a volume output of a speaker 217. The volume controller 213 is decoupled from the display circuitry 218 to prevent the volume controller from adjusting the displayed amplitude on the display device 208.

A memory 211a is electrically coupled to the MCU 211c and configured to store a shared key which is exclusive to the receiver 200 and the transmitter 100 paired therewith. The MCU 211c is configured to extract a decoded key from the calibrated audio frequency magnetic flux picked-up signal, i.e. output of block 219b, and ascertain whether the decoded key matches the shared key stored in the memory 211a of the receiver 200. If the decoded key does not match the shared key stored in the memory 211a, a notification is presented. Such notification may take on one or more forms including, but not limited to, display an error indication on the display device, inactivate the display device 208 to prevent display of the detected signal amplitude, etc.

Embodiments of the invention are advantageous in view of at least the following:

The method and apparatus are factory calibratable to the most popular power cable type in utility circuits to form a normalised signal magnitude level.

The method and apparatus are field calibratable to different underground multiconductor power cable types to overcome variant signal flux attenuation effect due to the differences from the cable type.

The method and apparatus use a Piecewise Linear Multiple Virtual Sensitivity (PLMVS) relationship to form normalised signal level, block floor noise and boost spatial resolution for cables in close proximity.

The method is not subject to various interferences as explained below:
(i) Electro-magnetic interference from the adjacent cables voltage and current: LV (Low Voltage, e.g. 400V), MV (Medium Voltage, e.g. 6.6 kV to 22 kV), HV (High Voltage, e.g. 66 kV) and current up to thousand Amperes.
(ii) Acoustic interference from, e.g. the traffic road side noise.
(iii) Close proximity interference. As power cables could be as close as 2 cm apart, the measuring point could be too close to the adjacent cable surface which causes the ambiguity of the true signal source cable. In additional to PLMVS, the invention provides a magnetic shield for holding the pick-up coil to clear proximity interferences and boost the difference in peak amplitude of closely-proximate cables.
(iv) Interference to the maximum display of calibrated signal level due to audio speaker volume adjustment. The receiver speaker control 213 is de-coupled from the ADC input signal 211e. Adjustment of volume can be performed by a human user based on his personal hearing comfort level without affect the true magnitude indication on the display device.
Health checking features are provided in transmitter and receiver. When the transmitter is switched on at first end substation, it runs a verification test to check if the circuit of audio frequency current signal injection is complete or not. At the receiver in the joint pit, the pick-up coil can be placed near the speaker of the receiver to cause a short moment resonance as functionality check.
Both transmitter and receiver use the same type high accuracy crystal (e.g. 30 ppm) as the audio frequency root reference clock source. The injected current signal frequency is chosen within audible frequency range (e.g. 1023 Hz) and avoids being any harmonics of the mains hum frequency e.g. 50 Hz). The receiver uses an optimized analogue ultra-narrow bandpass filter with exactly the same center frequency as the injected signal frequency. For example, the receiver filter is a switched capacitor based 8th order analogue butterworth centered at 1023 Hz. With filter switch 204 set to ON, this will remove electromagnetic interference that has a different frequency as the injected signal, especially the very strong electromagnetic interference from adjacent power cable carrying current up to thousand amperes.
The outputs 107 of the transmitter connect to a pair of conductors inside the target dead power cable at First End Substation and use zero Ohm jumper wire or switchgear's earthing switch to short and ground this pair at their Second End Substation to form a complete circuit of this pair of conductors. There is no earth connection to this pair of conductors at the First End Substation but the connection to the signal transmitter's two output ends. Since the current directions in the pair of conductors are opposite to each other, this will cancel any signal mutual induction to adjacent cables. The earthing at the Second End Substation also ensures the safety of the human user.
The Filter Bypass Selection (204 in FIG. 8A) at the receiver allows filter bypass to enable pick up of mains hum as verification of whether the cable under test is energized and loaded. This effectively prevents the spiking into the neighbouring cables which are live in operation and service.

It is to be understood that the embodiments and features described above should be considered exemplary and not restrictive. Many other embodiments will be apparent to those skilled in the art from consideration of the specification and practice of the invention. The scope of the invention should, therefore, be determined with reference to the appended claims, along with the full scope of equivalents to which such claims are entitled. Furthermore, certain terminology has been used for the purposes of descriptive clarity, and not to limit the disclosed embodiments of the invention. The entire disclosures of all references, applications, patents, and publications cited above are hereby incorporated by reference.

What is claimed is:

1. A non-clamping method for identification of target dead underground power cable, the method comprising:
forming a compete circuit by connecting a transmitter to two of a plurality of conductors of a target dead power cable at a first end thereof;
short-circuiting and grounding the plurality of conductors at a second end of the target dead power cable;
injecting an audio frequency current signal from the transmitter into the complete circuit for generating an audio frequency magnetic flux signal on a surface of the target dead power cable;
within a pit which at least partially exposes a plurality of underground power cables:
detecting a first audio frequency magnetic flux signal on a surface of a random first one of the underground power cables;
detecting a second plurality of audio frequency magnetic flux signals on respective surfaces of some of the underground power cables being spatially-adjacent to the first one of the underground power cables;
identifying the first one of the underground power cables as the target dead power cable if a peak amplitude of the first audio frequency magnetic flux signal as displayed on a display device exceeds any peak amplitude of the second plurality of audio frequency magnetic flux signals as displayed on the display device by more than about 50%.

2. The method of claim 1, further comprising:
before detecting a first audio frequency magnetic flux signal on a surface of a random first one of the underground power cables, performing a complete circuit verification on the two of the plurality- of conductors of the target dead power cable.

3. The method of claim 1, wherein detecting a first audio frequency magnetic flux signal further includes:
broadcasting the detected first audio frequency magnetic flux signal over a speaker.

4. The method of claim 3, wherein detecting a first audio frequency magnetic flux signal further includes:
controlling a volume output of the speaker without affecting the peak amplitude of the first audio frequency magnetic flux signal being displayed on the display device.

5. The method of claim 1, wherein the first audio frequency magnetic flux signal and the second plurality of audio frequency magnetic flux signals have substantially same frequency as the injected audio frequency current signal.

6. The method of claim 1, wherein the injected audio frequency magnetic flux signal is encoded with a shared key which is exclusively stored in the transmitter and a receiver paired therewith, wherein detecting a first audio frequency magnetic flux signal further includes:
extracting a first decoded key from the first audio frequency magnetic flux signal,
if the first decoded key matches the shared key, displaying an amplitude of the first audio frequency magnetic flux signal on the display device, and
if the first decoded key does not match the shared key, presenting a notification wherein detecting a second plurality of audio frequency magnetic flux signals further includes:
extracting a second decoded key from each of the second plurality of audio frequency magnetic flux signals,
if the second decoded key matches the shared key, displaying an amplitude of the corresponding one of the second audio frequency magnetic flux signals on the display device, and
if the second decoded key does not match the shared key, presenting the notification.

7. The method of claim 6, wherein presenting the notification includes at least one of displaying an error indication on the display device and inactivating the display device.

8. The method of claim 1, wherein detecting a first audio frequency magnetic flux signal further includes:
longitudinally running a pick-up coil along a first lengthwise position on the surface of the first cable, wherein detecting a second plurality of audio frequency magnetic flux signals further includes:
longitudinally running the pick-up coil along a plurality of second lengthwise positions on the respective surfaces of the some of the underground power cables being spatially-adjacent to the first one of the underground power cables.

9. The method of claim 8, wherein the pick-up coil is geometrically centred on an arc-shaped magnetic shield.

10. The method of claim 1, further comprising:
grounding an armour of the target dead power cable at the first and the second end thereof.

11. A receiver for identification of target dead underground power cable, the receiver comprising:
an amplifier circuity configured to amplify a picked-up signal by a user-adjustable gain;
a by-passable switched capacitor analogue ultra-narrow bandpass filter configured to filter an output of the amplifier circuitry;
a gain calibrator circuitry configured to calibrate an output of the by-passable switched capacitor analogue ultra-narrow bandpass filter to form a normalised signal level;
a speaker circuitry configured to broadcast an output of the gain calibrator circuitry;
a micro-controller unit (MCU) having an Analogue Digital Converter (ADC) configured to digitise the output of the gain calibrator circuitry;
a display circuitry configured to receive an output of the MCU to provide a visual indication thereof on a display device, wherein a displayed magnitude of the visual indication is correlated to an amplitude of an audio frequency magnetic flux signal comprised in the picked-up signal.

12. The receiver of claim 11, wherein the receiver further comprises a volume controller coupled to the speaker circuitry for adjusting a volume output of a speaker, wherein the volume controller being decoupled from the display circuitry to prevent the volume controller from adjusting the visual indication.

13. The receiver of claim 11, further comprising:
a pick-up coil configured to provide the picked-up signal to the amplifier circuitry.

14. The receiver of claim 13, wherein the pick-up coil is geometrically centred on an arc-shaped magnetic shield.

15. The receiver of claim 11, further comprising:
a memory circuitry configured to store a shared key which is exclusive to the receiver and the transmitter paired therewith,
wherein the MCU is configured to extract a decoded key from the output of the gain calibrator circuitry, compare the decoded key against the shared key stored in the memory circuitry, present a notification if the decoded key does not match the shared key.

16. The receiver of claim 15, wherein the MCU is further configured to present the notification by at least one of presenting an error indication on the display device and inactivating the display device.

17. The receiver of claim 11, wherein the ADC is further configured to digitise the output of the gain calibrator circuitry based on a plurality of piecewise linear sensitivity relationships.

18. A transmitter for identification of target dead underground power cable, the transmit comprising:
a micro-controller unit (MCU) having an audio signal generator configured to generate an audio frequency voltage signal;
a current selector circuitry configured to preset a peak pulse amplitude;
a constant peak current source circuitry configured to convert the audio frequency voltage signal into an audio frequency current signal having the preset peak pulse amplitude;
an output protection circuitry electrically coupled between the constant peak current source circuitry and a pair of output terminals, and configured to prevent over-current and over-voltage damage to the transmitter, wherein the pair of output terminals are configured to inject the audio frequency current signal into a pair of conductors of a target dead power cable.

19. The transmitter of claim 18, further comprising:
a sensing circuitry configured to ascertain a presence of complete circuit in the pair of conductors of the target dead power cable; and
a display circuitry configured to present a result based on the ascertained presence of complete circuit in the pair of conductors of the target dead power cable.

20. The transmitter of claim 18, further comprising:
a memory circuitry configured to store a shared key which is exclusive to the receiver and the transmitter paired therewith, wherein the WU is configured to encode the shared key into the audio frequency voltage signal.
